(19) United States
(12) Patent Application Publication
(10) Pub. No.: US 2016/0266205 A1
(43) Pub. Date: Sep. 15, 2016

(54) LOGIC VERIFICATION APPARATUS, LOGIC VERIFICATION METHOD AND TEST PROGRAM

(71) Applicant: FUJITSU LIMITED, Kawasaki-shi (JP)

(72) Inventor: Takanori INAGAKI, Kawasaki (JP)

(73) Assignee: FUJITSU LIMITED, Kawasaki-shi (JP)

(21) Appl. No.: 15/048,334

(22) Filed: Feb. 19, 2016

(30) Foreign Application Priority Data
Mar. 10, 2015 (JP) 2015-046876

(51) Int. Cl. G01R 31/317; G01R 31/3177

(52) U.S. Cl. CPC G01R 31/31703; G01R 31/3177; G01R 31/31712

(57) ABSTRACT

A logic verification apparatus configured to test an operation of a simulation device under test that processes a plurality of responses that are sequentially received from a simulation I/O device in accordance with the plurality of instructions transferred to the simulation I/O device, the logic verification apparatus includes: an error generation section configured to cause, when the simulation device receives the instructions, the responses and a target instruction from the simulation arithmetic processing device in a predetermined order, an error to be generated in a result of processing of the target instruction performed by the simulation device; an error holding section configured to hold error generation information indicating that the error was generated; and a response comparison section configured to compare a target response corresponding to the target instruction, with one of a plurality of expectation values.

### CROSS-REFERENCE TO RELATED APPLICATION

This application is based upon and claims the benefit of priority of the prior Japanese Patent Application No. 2015-046876, filed on Mar. 10, 2015, the entire contents of which are incorporated herein by reference.

### FIELD

The embodiments discussed herein are related to a logic verification apparatus, a logic verification method, and a test program.

### BACKGROUND

As the performance and function of devices, such as large scale integration (LSI) devices and the like, increase, the performance and function of systems in which such a device is mounted increase, and factors for causing defects tend to be complicated. Therefore, a new method for testing or verifying a logic of an operation of a device has been proposed.

For example, a simulator that tests a plurality of devices coupled to one another via a bus causes an error generation section to generate an error, based on a state of a system, which is described in a test scenario, to test an operation when the error is generated (see, for example, Japanese Laid-open Patent Publication No. 2007-58431).

A test of a system including an input and output (I/O) device is executed using a simulation (i.e. pseudo) I/O device that generates an error when a predetermined condition, such as a timing or an address value set in a setting file, and the like, is satisfied (see, for example, Japanese Laid-open Patent Publication No. 2003-44369).

A simulator that tests logics of a plurality of circuits that transmit information via a bus causes a bus module to artificially generate a transmission delay and a transmission error on a bus and thus test the logics as well as characteristics of the bus (see, for example, Japanese Laid-open Patent Publication No. 2012-22613).

There are cases where an error in a device is caused to be generated by a combination of a plurality of factors generation timings of which are different from one another, but no method for testing an operation of a device when such an error is generated in a device has been yet proposed.

According to an aspect, it is an object of the present disclosure to provide a logic verification apparatus, a logic verification method, and a test program each of which is configured to sequentially transfer a plurality of instructions and execute a test of an operation of a device under test, also called as a DUT, that receives responses corresponding to the transferred instructions in a more detail manner, as compared to a known technology.

### SUMMARY

According to an aspect of the invention, an a logic verification apparatus configured to sequentially transfer a plurality of instructions that are sequentially received from a simulation (pseudo) arithmetic processing device that simulates an operation of an arithmetic processing device to a simulation (pseudo) I/O device that simulates an operation of an I/O device and to test an operation of a device (DUT) that processes a plurality of responses that are sequentially received from the simulation I/O device in accordance with the plurality of instructions transferred to the simulation I/O device, the apparatus includes: an error generation section configured to cause, when the simulation device receives at least one of the plurality of instructions and the plurality of responses and a target instruction from the simulation arithmetic processing device in a predetermined order, an error to be generated in a result of processing of the target instruction performed by the simulation device; an error holding section configured to hold error generation information indicating that the error was generated in a result of processing of the target instruction; and a response comparison section configured to compare a target response, among the plurality of responses received by the simulation device, which corresponds to the target instruction, with one of a plurality of expectation values, based on the error generation information held in the error holding section.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating an embodiment for a logic verification apparatus, a logic verification method, and a test program, for a DUT;

FIG. 2 is a diagram illustrating another embodiment for a logic verification apparatus, a logic verification method, and a test program;

FIG. 3 is a diagram illustrating an example of a target device illustrated in FIG. 2;

FIG. 4 is a diagram illustrating an example of an error production section illustrated in FIG. 2;

FIG. 5 is a diagram illustrating an example of a decoding section illustrated in FIG. 4;

FIG. 6 is a flow chart illustrating an example of an operation of the error production section illustrated in FIG. 4;

FIG. 7 is a flow chart illustrating an example of an operation of a response comparison section of a test scenario execution section illustrated in FIG. 2;

FIG. 8 is a view illustrating an example of a test scenario that is executed by the test scenario execution section illustrated in FIG. 2;

FIG. 9 is a view illustrating another example of the test scenario that is executed by the test scenario execution section illustrated in FIG. 2;

FIG. 10 is a view illustrating another example of the test scenario that is executed by the test scenario execution section illustrated in FIG. 2;

FIG. 11 is a diagram illustrating an example of an information processing device that operates as a logic verification apparatus illustrated in FIG. 2;

FIG. 12 is a diagram illustrating another embodiment for a logic verification apparatus, a logic verification method, and a test program;

FIG. 13 is a diagram illustrating an example of a target device illustrated in FIG. 12;

FIG. 14 is a diagram illustrating an example of an error production section illustrated in FIG. 12;

FIG. 15 is a diagram illustrating another embodiment for a logic verification apparatus, a logic verification method, and a test program; and

FIG. 16 is a diagram illustrating an example of an error production section illustrated in FIG. 15.

### DESCRIPTION OF EMBODIMENTS

Embodiments will be described below with reference to the accompanying drawings.

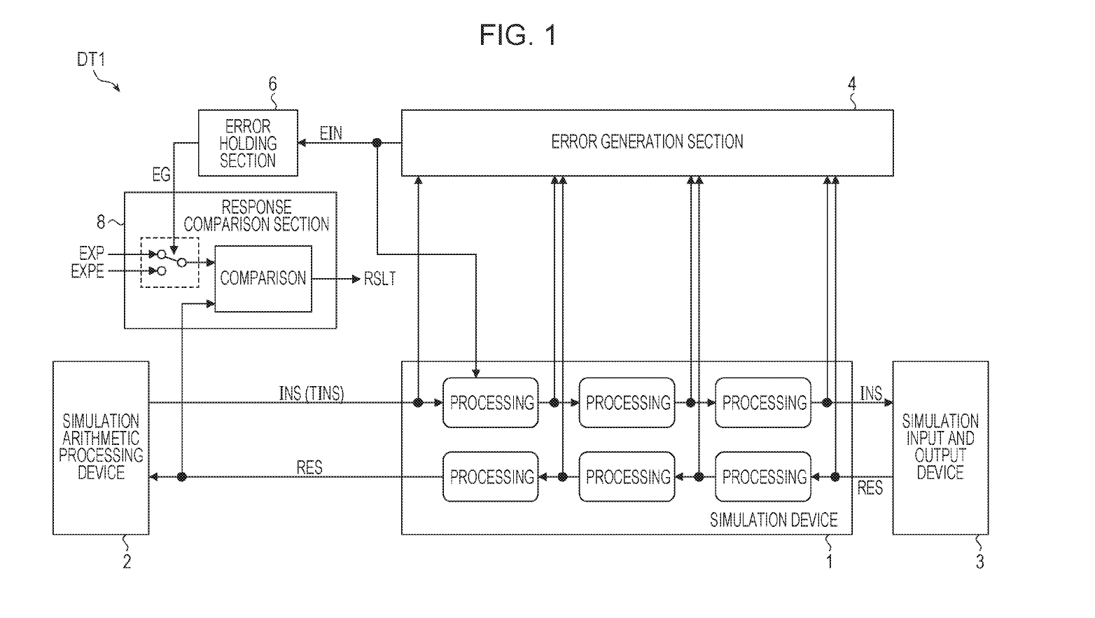

FIG. 1 illustrates an embodiment for a logic verification apparatus, a logic verification method, and a test program. A logic verification apparatus, also called as a simulation device test apparatus herein after, DT1 illustrated in FIG. 1 tests or verifies an operation of a DUT, namely, an LSI or the like, using a simulation device 1 that simulates an operation of the DUT. The term “simulation” here is used as a synonym of “pseudo”. The simulation device 1 sequentially transfers a plurality of instructions INS that the simulation device 1 sequentially receives from a simulation arithmetic processing device 2 that simulates an operation of an arithmetic processing device to a simulation (or pseudo) I/O device 3 that simulates an operation of an I/O device. Also, the simulation device 1 processes a plurality of responses RES that the simulation device 1 sequentially receives from the simulation I/O device 3 in accordance with the plurality of instructions INS transferred to the simulation I/O device 3. The simulation device 1 may transmit the processed responses RES to the simulation arithmetic processing device 2 that is a transmission source of the instructions INS. In FIG. 1, the simulation device 1 executes each of processing that is performed three times for one instruction INS and processing that is performed three times for one response RES in one cycle. Note that each of the number of times the simulation device 1 processes one instruction INS and the number of times the simulation device 1 processes one response RES is not limited to three as illustrated in FIG. 1. For example, in processing executed by the simulation device 1 on each of the instructions INS, an actual body of the instruction INS is not changed, and information included in the instruction INS is extracted or information is added to the instruction INS. Similarly, in processing executed by the simulation device 1 on each of the responses RES, an actual body of the response RES is not changed, and information included in the response RES is extracted or information is added to the response RES.

For example, the logic verification apparatus DT1 causes an information processing device or the like to execute a test program used for testing an operation of the simulation device 1 and thereby realizes a logic verification method. The simulation device 1 is represented by design data, such as a circuit description of an LSI or the like, and the like, which is simulated by the simulation device 1. The simulation arithmetic processing device 2 has a function of transmitting the instructions INS and receiving the responses RES, among functions of an arithmetic processing device, and the simulation I/O device 3 has a function of receiving the instructions INS and transmitting the responses RES, among functions of inputting and outputting information. Note that the logic verification apparatus DT1 may be realized by a hardware. An actual device may be used for at least one of the simulation device 1, the simulation arithmetic processing device 2, and the simulation I/O device 3. Also, a simulation device other than the simulation arithmetic processing device 2 and the simulation I/O device 3 may be coupled to the simulation device 1.

The logic verification apparatus DT1 includes an error generation section 4, an error holding section 6, and a response comparison section 8. The error generation section 4 is programmed in advance so as to output, when the simulation device 1 receives at least one of the plurality of instructions INS and the plurality of responses RES and a target instruction TINS, for which an error to be generated, in a predetermined order from the simulation arithmetic processing device 2, generation information EIN. The generation information EIN indicates that an error is to be generated in a result of processing of the target instruction TINS performed by the simulation device 1, and is output to the simulation device 1 and the error holding section 6. The generation information EIN may be one bit, which indicates whether or not an error is to be generated, so that only an error of one type is generated, and may be multiple bits so that one of errors of a plurality of types is applied in accordance with the value of the generation information EIN. The simulation device 1 causes an error to be generated in the target instruction TINS, based on the generation information EIN. Note that, in FIG. 1, the generation information EIN is coupled to only one of processing sections, but may be coupled to multiple ones or all of processing sections, as appropriate.

For example, when the error generation section 4 receives a predetermined instruction INS two cycles before receiving the target instruction TINS, the error generation section 4 outputs the generation information EIN. As another option, when the error generation section 4 receives a response RES corresponding to a predetermined instruction INS one cycle before receiving the target instruction TINS, the error generation section 4 outputs the generation information EIN. That is, the error generation section 4 outputs the generation information EIN, based on a combination of the target instruction TINS that is processed by the simulation device 1, another instruction, and a response. On the other hand, when the simulation device 1 does not receive at least one of the plurality of instructions INS and the plurality of responses RES and the target instruction TINS in a predetermined order, the error generation section 4 does not output the generation information EIN.

Note that, when the simulation device 1 receives the plurality of instructions INS including the target instruction TINS in a predetermined order without referring to the responses RES, the error generation section 4 may output the generation information EIN. Also, the error generation section 4 may take out information included in the target instruction TINS that is being processed by the simulation device 1, cause an error to be generated in the taken out information, and return the information in which an error was generated back to the target instruction TINS that is being processed by the simulation device 1. That is, an error may be generated in the error generation section 4.

Based on reception of the generation information EIN, the error holding section 6 holds error generation information EG indicating that an error was generated in a result of processing of the target instruction TINS and outputs the held error generation information EG to the response comparison section 8.

When the response comparison section 8 receives the error generation information EG indicating that an error was generated in a result of processing of the target instruction TINS, the response comparison section 8 compares a target response, which is one of the responses RES, which was received by the simulation device 1 in accordance with the target instruction TINS, with an expectation value EXPE when an error was generated. On the other hand, when the response comparison section 8 does not receive the error generation information EG, the response comparison section 8 compares a target response received by the simulation device 1 in accordance with the target instruction TINS with an expectation value EXP when an error was not generated.

Then, if the response RES and the expectation value EXPE match each other or if the response RES and the expectation value EXP match each other, the response comparison section 8 outputs a test result RSLT indicating that the simulation device 1 correctly operated. On the other hand, if the response RES and the expectation value EXPE do not match each other or if the response RES and the expectation value EXP do not match each other, the response comparison section 8 outputs the test result RSLT indicating that the simulation device 1 did not correctly operate. That is, a test (a logic verification method) of an operation of the simulation device 1 of the logic verification apparatus DT1 is executed.

As has been described above, in the embodiment illustrated in FIG. 1, whether or not an error is to be generated may be selected not by causing an error to be generated in all of the target instructions TINS and performing comparison with the expectation value EXPE, but, based on an instruction or a response, which is being processed by the simulation device 1 when the target instruction TINS is received. As a result, the plurality of instructions INS may be sequentially transferred, a test of an operation of the simulation device 1 that processes the plurality of responses RES that the simulation device 1 sequentially receives in accordance with the transferred instructions INS may be executed with a more complex condition than that in a known technology, and a detailed test may be executed.

Both of a test when an error was generated and a test when an error was not generated may be executed using one of the two expectation values EXP and EXPE by causing the error holding section 6 to hold the error generation information EG indicating whether or not an error was generated. Thus, the efficiency of a test may be increased, as compared to when the test is executed using a single expectation value.

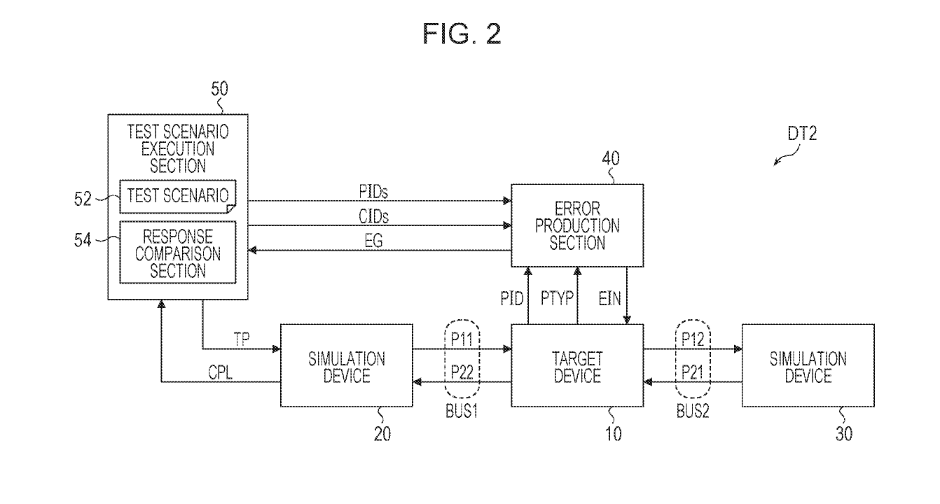

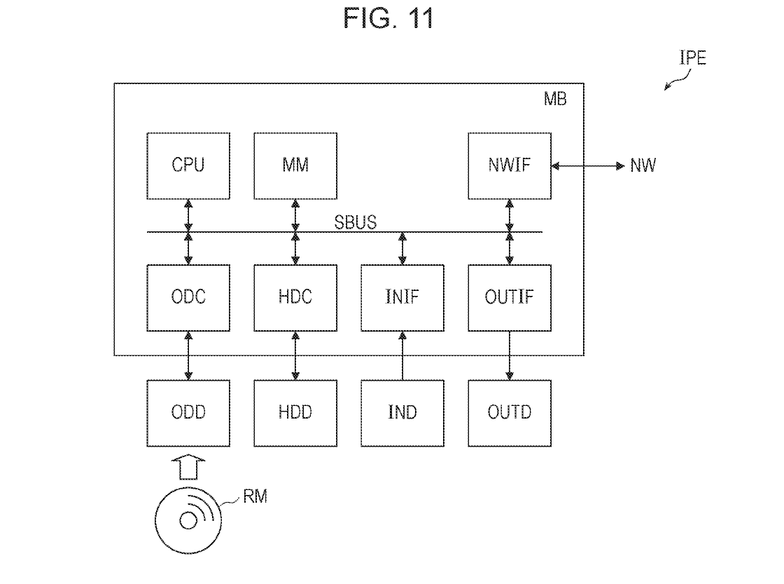

FIG. 2 illustrates another embodiment for a logic verification apparatus, a logic verification method, and a test program. For example, a logic verification apparatus DT2 illustrated in FIG. 2 is realized by an information processing device that executes a test program used for testing a logic of a target device (i.e., a DUT) 10. The information processing device that executes the test program functions as a simulator and executes an operation based on a logic verification method for testing the logic of the target device 10. An example of the information processing device that realizes the logic verification apparatus DT2 is illustrated in FIG. 11.

The logic verification apparatus DT2 includes the target device 10, which is a test target (or a DUT), a simulation device 20 coupled to the target device 10 via a bus BUS1, and a simulation device 30 coupled to the target device 10 via a bus BUS2. Also, the logic verification apparatus DT2 includes an error production section 40 that produces the generation information EIN that causes an error to be generated in the target device 10, and a test scenario execution section 50 that executes a test scenario 52 to test the logic of the target device 10. The error production section 40 corresponds to the error generation section 4 in FIG. 1. Here, the term “produce” or “production” is used as a synonym of “generate” or “generation”.

The target device 10 has a function of processing a packet P11 received from the simulation device 20 via the bus BUS1 and transferring the packet P11 as a packet P12 to the simulation device 30 via the bus BUS2. Also, the target device 10 has a function of processing a packet P21 received from the simulation device 20 via the bus BUS2 and transferring the packet P21 as a packet P22 to the simulation device 20 via the bus BUS1. For example, each of the buses BUS1 and BUS2 is a peripheral component interconnect (PCI) bus or a PCI express (registered Trademark) bus. The packets P11, P12, P21, and P22 are transmitted on the buses BUS1 and BUS2 in accordance with standards of PCI or PCIe. Note that the buses BUS1 and BUS2 may be buses in accordance with other bus standards.

The simulation device 20 has a function of transmitting the packet P11 to the bus BUS1 and a function of receiving the packet P22 from the bus BUS1, among functions of an arithmetic processing device, such as a central processing unit (CPU) and the like. The simulation device 20 operates in accordance with a test pattern TP that is output from the test scenario execution section 50.

The simulation device 30 has a function of receiving the packet P12 from the bus BUS2 and a function of transmitting the packet P21 to the bus BUS2, among functions of a peripheral device, such as an I/O device and the like, an operation of which is controlled by the simulation device 20 (the arithmetic processing device, such as a CPU and the like). That is, the simulation device 20 has an interface function with the target device 10, among functions of the CPU, and the simulation device 30 has an interface function with the target device 10, among functions of the I/O device that is controlled by the CPU. The target device 10 is an example of a simulation device that transfers a plurality of instructions that the target device 10 sequentially receives from the simulation device 20 to the simulation device 30 and processes a plurality of responses that the target device 10 sequentially receives from the simulation device 30. The simulation device 20 is an example of a simulation arithmetic processing device that simulates an operation of the arithmetic processing device, and the simulation device 30 is an example of a simulation I/O device that simulates an operation of the I/O device.

When, in response to the packet P11 transmitted by the simulation device 20, the simulation device 30 sends back the packet P21, the packets P21 and P22 are handled as response packets. In this case, the packets P11 and P12 are examples of instructions, and the packets P21 and P22 are examples of responses corresponding to the instructions P11 and P12. Also, when, in response to the packet P21 transmitted by the simulation device 30, the simulation device 20 sends back the packet P11, the packets P11 and P12 are handled as response packets.

For example, the target device 10 has a function of a switch coupled between the CPU and the I/O device, and is represented by design data, such as a circuit description of a switch and the like. Note that the target device 10 may have a function of a bridge coupled between the CPU and the I/O device. Then, the logic verification apparatus DT2 tests a logic of the switch or the bridge coupled between the CPU and the I/O device. By using the simulation devices 20 and 30 each of which has an interface function with the target device 10, the logic of the switch coupled to the CPU and the I/O device via the buses BUS1 and BUS2 may be tested at a system level.

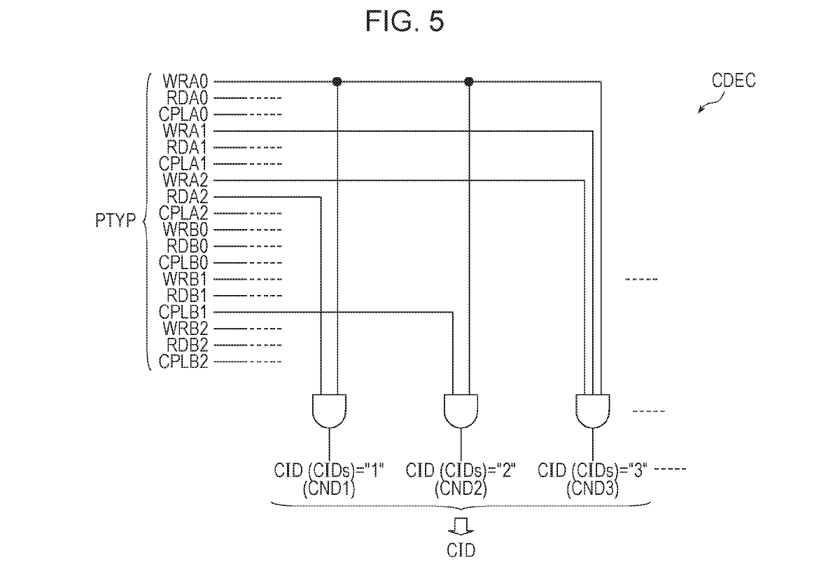

The error production section 40 receives an identification number PIDs that identifies the target packet P11 in which an error is to be generated and an identification number CIDs that identifies a condition for causing an error to be generated in the packet P11 from the test scenario execution section 50. The packet P11 that is identified by the identification number PIDs is an example of a target instruction for which an error is to be generated. The identification number CIDs is an example of order information indicating an order in which at least one of the plurality of packets P11 and the plurality of response packets P21 and the packet P11 indicated by the identification number PIDs are supplied to the target device 10. In other words, the identification number CIDs indicates a combination of the packets P11 and P21, which is a condition for causing an error to be generated. An example of the combination of the packets P11 and P21 indicated by the identification number CIDs is illustrated in FIG. 5.

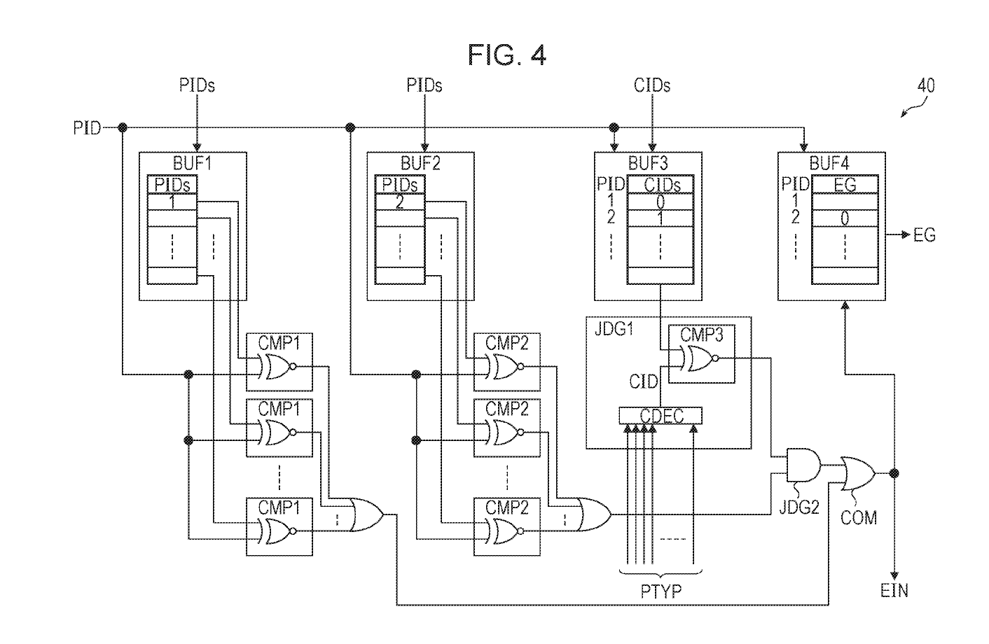

The error production section 40 receives an identification number PID that identifies the packet P11 received by the target device 10 and type information PTYP indicating the types of the plurality of packets P11 and P21 that are sequentially processed in the target device 10 from the target device 10. The error production section 40 produces an identification number CID (FIG. 4) indicating a combination of the plurality of packets P11 and P21 that are being processed by the target device 10, based on the type information PTYP.

If the identification number PID matches the identification number PIDs, the error production section 40 outputs the generation information EIN that causes an error to be generated in the packet P11 to the target device 10. As another option, if the identification number PID matches the identification number PIDs and the identification number CID corresponding to the type information PTYP matches the identification number CIDs, the error production section 40 outputs the generation information EIN to the target device 10. A condition for outputting the generation information EIN is illustrated in FIG. 4. Based on the generation information EIN, the target device 10 embeds an error in the packet P11 and thus transmits the packet P11 as the packet P12 to the simulation device 30. That is, the error production section 40 inserts an error in the packet P11 identified by the identification number PIDs, among the packets P11 that are being processed by the target device 10. The error production section 40 outputs the error generation information EG indicating that an error was embedded to the test scenario execution section 50, based on the output of the generation information EIN.

The simulation device 30 executes internal processing, based on the received packet P12, and transmits the packet P21 (a response packet) indicating an execution result of the internal processing to the target device 10. The target device 10 processes the packet P21 and thus transmits the packet P21 as the packet P22 to the simulation device 20.

Note that the type information PTYP may indicate not only the types of the plurality of packets P11 from the simulation device 20, which are sequentially held in the target device 10, but also the types of the plurality of response packets P21 from the simulation device 30, which are sequentially held in the target device 10. In this case, the test scenario execution section 50 transmits the identification number CIDs indicating a combination of the packet P11 that is transmitted from the simulation devices 20 to the target device 10 and the response packet P21 that is transmitted from the simulation device 30 to the target device 10 to the error production section 40. The error production section 40 produces the identification number CID indicating a combination of the plurality of packets P12 and P21 held by the target device 10, and determines whether or not the identification numbers CID and CIDs match each other.

In accordance with the test scenario 52, the test scenario execution section 50 outputs the test pattern TP that causes the simulation device 20 to operate to the simulation device 20, and also outputs the identification numbers PIDs and CIDs to the error production section 40. When the identification number PIDs is designated without designating the identification number CIDs and thus an error is embedded in the packet P11, regardless of the error generation information EG, the test scenario execution section 50 causes a response comparison section 54 to compare information CPL included in the response packet P22 with an expectation value. The response packet P22 corresponding to the packet P11 in which an error is embedded is an example of a target response.

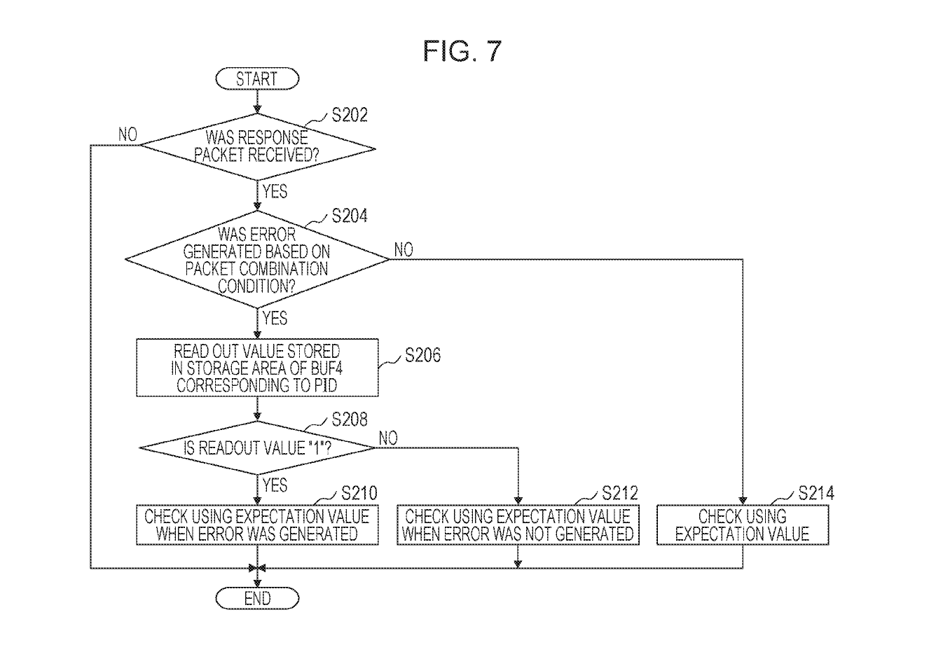

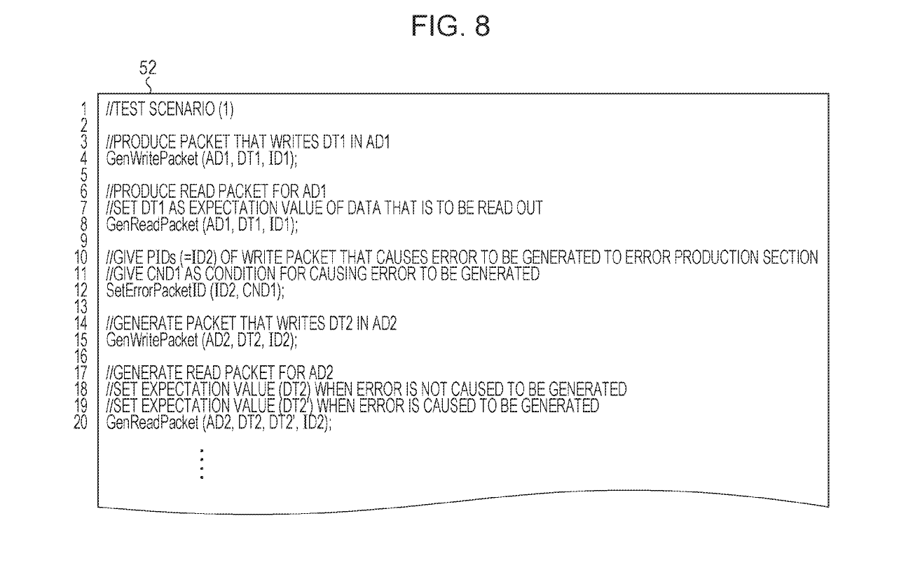

On the other hand, when the identification number CIDs (an error generation condition) is designated as well as the identification number PIDs and thus an error is embedded in the packet P11, the test scenario execution section 50 causes the response comparison section 54 to execute comparison based on the error generation information EG. That is, the response comparison section 54 compares the information CPL included in the response packet P22 with one of two expectation values. An example of an operation of the response comparison section 54 is illustrated in FIG. 7, and an example of the test scenario 52 that is executed by the test scenario execution section 50 is illustrated in FIG. 8 to FIG. 10.

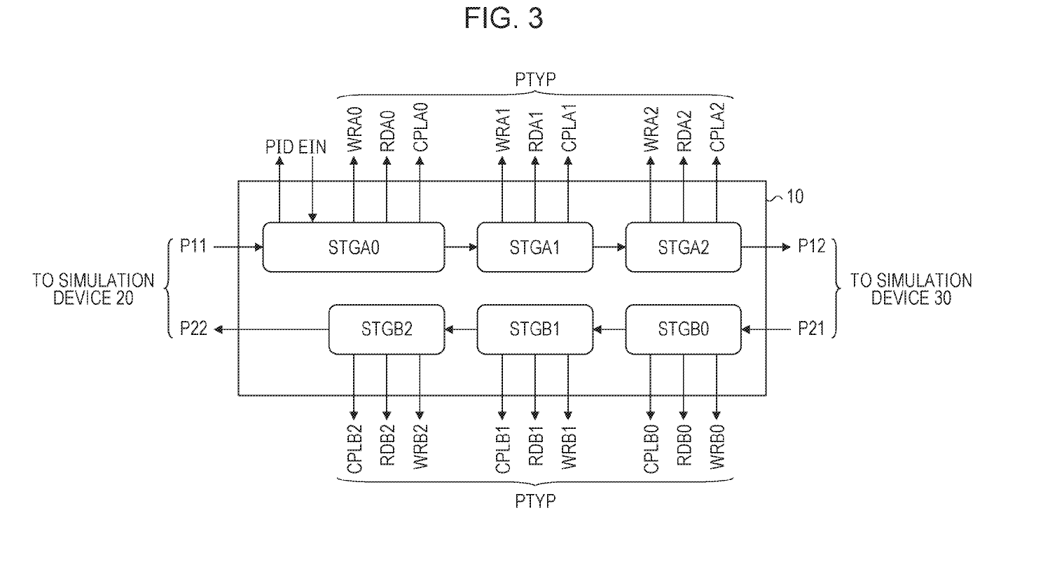

FIG. 3 illustrates an example of the target device 10 illustrated in FIG. 2. The target device 10 includes processing sections STGA (STGA0, STGA1, and STGA2) that sequentially processes the packet P11 to produce the packet P12. Also, the target device 10 includes processing sections STGB (STGB0, STGB1, and STGB2) that sequentially processes the packet P21 to produce the packet P22. Each of the processing sections STGA and STGB has a function of extracting or erasing information included in a received packet or adding information to a received packet.

Furthermore, the processing section STGA0 has a function of extracting the identification number PID included in the packet P11 received from the simulation device 20 and outputting the extracted identification number PID to the error production section 40 illustrated in FIG. 2. Also, the processing section STGA0 has a function of embedding, when the processing section STGA0 receives the generation information EIN from the error production section 40, an error in information included in the packet P11. Note that the function of embedding an error may be provided in the processing section STGA1 or the processing section STGA2 and, as another option, may be provided also in the processing sections STGB0 to STGB2. The function of generating an error is provided in the processing section STGA1 or the processing section STGA2, so that the packet P11 that is supplied to the target device 10 after the packet P11 corresponding to the identification number PID may be included in an condition for causing an error to be generated.

If the packet P11 that is to be processed is a write packet, each of the processing sections STGA outputs packet information WRA (WRA0, WRA1, and WRA2) as the type information PTYP. If the packet P11 that is to be processed is a read packet, each of the processing sections STGA outputs packet information RDA (RDA0, RDA1, and RDA2) as the type information PTYP. A write packet is produced when the simulation device 20 writes data in a predetermined area of the simulation device 30, and a read packet is produced when the simulation device 20 reads out data from a predetermined area of the simulation device 30.

Also, if the packet P11 that is to be processed is a response packet responding to a write packet or a response packet responding to a read packet, each of the processing sections STGA outputs packet information CPLA (CPLA0, CPLA1, and CPLA2) as the type information PTYP. A response packet is produced by the simulation device 30 that has received a write packet or a read packet, and a response packet responding to a read packet includes read data.

If the packet P21 that is to be processed is a write packet, each of the processing sections STGB outputs packet information WRB (WRB0, WRB1, and WRB2) as the type information PTYP. If the packet P21 that is to be processed is a read packet, each of the processing sections STGB outputs packet information RDB (RDB0, RDB1, and RDB2) as the type information PTYP. Also, if the packet P21 that is to be processed is a response packet responding to a write packet or a response packet responding to a read packet, each of the processing sections STGB outputs packet information CPLB (CPLB0, CPLB1, and CPLB2) as the type information PTYP. Note that each of the “response packets” indicates that reception of a write packet or a read packet is completed, but does not indicate that processing of writing or reading is completed.

Note that each of the number of the processing sections STGA and the number of the processing sections STGB is not limited to three and the types of packet information output by each of the processing sections STGA and STGB are not limited to three types.

FIG. 4 illustrates an example of the error production section 40 illustrated in FIG. 2. The error production section 40 includes buffers BUF1, BUF2, BUF3, and BUF4, a plurality of comparison sections CMP1, a plurality of comparison sections CMP2, determination sections JDG1 and JDG2, and a combining section COM. The buffers BUF1, BUF2, and BUF3, the plurality of comparison sections CMP1, the plurality of comparison sections CMP2, and the determination section JDG1 are of an example of the error generation section that causes an error to be generated in a result of processing of the packet P11, which is processed in the target device 10. The buffer BUF1 is an example of the third holding section, the buffer BUF2 is an example of the first holding section, the buffer BUF3 is an example of the second holding section, and the buffer BUF4 is an example of the error holding section. Each of the comparison sections CMP1 is an example of the third detection section, each of the comparison sections CMP2 is an example of the first detection section, and the comparison section CMP3 is an example of the order comparison section. The determination section JDG1 is an example of the second detection section.

The buffer BUF1 includes a plurality of storage areas in which the identification number PIDs output from the test scenario execution section 50 illustrated in FIG. 2 is sequentially stored, and outputs the stored identification number PIDs to the comparison sections CMP1 each of which corresponds to the corresponding one of the plurality of storage areas. The identification number PIDs is produced by the test scenario execution section 50, based on the test scenario 52 that is executed by the test scenario execution section 50. The plurality of comparison sections CMP1 is provided such that each of the comparison sections CMP1 corresponds to the corresponding one of the storage areas of the buffer BUF1. Each of the comparison sections CMP1 detects that the identification number PID from the target device 10 and one of the identification numbers PIDs from the buffer BUF1 match each other. Each of the comparison sections CMP1 calculates a non-exclusive OR of each bit of multiple bits representing the identification number PID and each bit of multiple bits representing the identification number PIDs output from the buffer BUF1, and thereby detects that the identification number PID and one of the identification numbers PIDs match each other. If the identification number PID and any one of the identification numbers PIDs match each other, each of the comparison sections CMP1 outputs a logic 1 to the combining section COM.

In the example illustrated in FIG. 4, if the identification number PID is “1” stored in one of the storage areas of the buffer BUF1, one of the comparison sections CMP1 outputs the logic 1 to the combining section COM. If the combining section COM receives the logic 1 from the determination section JDG2 or one of the comparison sections CMP1, the combining section COM outputs the generation information EIN to the target device 10 in order to embed an error in the packet P11. If the combining section COM receives a logic 0 from both of the determination section JDG2 and the comparison sections CMP1, the combining section COM inhibits output of the generation information EIN to the target device 10 in order not to embed an error in the packet P11. The combining section COM allows embedding of an error in the packet P11, based on information held in the buffer BUF1 or information held in the buffers BUF2 and BUF3. That is, both when a condition of the order of the packet P11 is included in the packet P11 and when the condition of the order of the packet P11 is not included in the packet P11, an error may be embedded in the packet P11, and the logic of the target device 10 may be tested using various conditions.

The buffer BUF2 includes a plurality of storage areas in which the identification number PIDs output from the test scenario execution section 50 is sequentially stored, and outputs the stored identification number PIDs to the comparison sections CMP2 each of which corresponds to the corresponding one of the plurality of storage areas. The plurality of comparison sections CMP2 is provided such that each of the comparison sections CMP2 corresponds to the corresponding one of the storage areas of the buffer BUF2. Each of the comparison sections CMP2 detects that the identification number PID from the target device 10 and one of the identification numbers PIDs from the buffer BUF2 match each other. Each of the comparison sections CMP2 calculates a non-exclusive OR of each bit of multiple bits representing the identification number PID and each bit of multiple bits representing the identification number PIDs output from the buffer BUF2, and thereby detects that the identification number PID and one of the identification numbers PIDs match each other. If the identification number PID and one of the identification numbers PIDs match each other, each of the comparison sections CMP2 outputs the logic 1 to the determination section JDG2.

The buffer BUF3 includes a plurality of storage areas in which the identification number CIDs is stored in accordance with each identification number PID. When the buffer BUF3 receives the identification number PID from the target device 10, the buffer BUF3 outputs the identification number CIDs stored in one of the storage areas, which corresponds to the identification number PID to the determination section JDG1. Note that “0” stored in the storage areas of the buffer BUF3 indicates an invalid identification number CIDs that is not a target of comparison performed by the comparison sections CMP.

The determination section JDG1 includes a decoding section CDEC and the comparison section CMP3. The decoding section CDEC decodes the type information PTYP output from the target device 10 to produce the identification number CID indicating a combination of packets indicated by the type information PTYP. The type information PTYP is an example of instruction information indicating the plurality of packets P11 and P21 received by the target device 10.

The comparison section CMP3 detects that the identification number CID produced by the decoding section CDEC and the identification number CIDs output from the buffer BUF3 in accordance with the identification number PID match each other. The comparison section CMP3 calculates a non-exclusive OR of each bit of multiple bits representing the identification number CID and each bit of multiple bits representing the identification number CIDs output from the buffer BUF3 and thereby detects that the identification number CID and CIDs match each other. If the identification numbers CID and CIDs match each other, the comparison section CMP3 outputs the logic 1 to the determination section JDG2. That is, if a combination of packets held in the processing sections STGA and STGB illustrated in FIG. 3 matches a combination for causing an error to be generated, which is designated in the test scenario 52, the comparison section CMP3 outputs the logic 1.

If one of the comparison sections CMP2 detects that the identification numbers PID and PIDs match each other and the comparison section CMP3 detects that the identification numbers CID and CIDs match each other, the determination section JDG2 outputs the logic 1 to the combining section COM in order to embed an error in the packet P11. Thus, when the target device 10 receives a predetermined packet P11, among the plurality of packets P11 that are targets in which an error is to be embedded, in the order indicated by the identification number CIDs, an error may be embedded in the target packet P11. That is, a condition for embedding an error in the packet P11 may be set in more detail, as compared to a known technology. Also, the test pattern TP may be reduced to be shorter than that when a packet group P11 of a plurality of combinations, including the target packet P11, is supplied to the target device 10 by a plurality of supplies without designating a condition. Thus, a time which it takes to test the target device 10 may be reduced, as compared to a known technology, and the efficiency of a test may be increased. Furthermore, each of the buffers BUF1, BUF2, and BUF3 includes the plurality of storage areas, so that a plurality of conditions for causing an error to be generated may be designated and the efficiency of a test may be further increased.

In the example illustrated in FIG. 4, if the identification number PID is “2” stored in the buffer BUF2 and the identification number CID is “1” stored in one of the storage areas of the buffer BUF3, which corresponds to the identification number PID, the determination section JDG2 outputs the logic 1 to the combining section COM.

The buffer BUF4 includes a plurality of storage areas in which the logic output by the combining section COM is stored in accordance with each identification number PID. The buffer BUF4 outputs, as the error generation information EG, the logic stored in one of the storage areas, which corresponds to the identification number PID from the target device 10, to the test scenario execution section 50. In FIG. 4, “0” stored in one of the storage areas of the buffer BUF4, which corresponds to the identification number PID=“2”, indicates that an error was not generated in a result of processing of a packet of the identification number PID=“2” performed by the target device 10.

A plurality of storage areas is provided in the buffer BUF4 for each target packet in which an error is to be generated, and thereby, a plurality of pieces of information indicating whether or not an error is to be generated may be held in buffer BUF4. Thus, in accordance with a single test scenario 52, a plurality of types of tests may be executed, and the efficiency of a test may be increased. Also, the plurality of storage areas of the buffer BUF4 is provided for each identification number PID of the target packet P11 in which an error is to be generated, and therefore, the buffer BUF4 may be commonly used in each of a test performed when the order of the packet P11 is designated and a test performed when the order of the packet P11 is not designated.

FIG. 5 illustrates an example of the decoding section CDEC illustrated in FIG. 4. The reference characters CND1, CND2, and CND3 illustrated so as to correspond to the identification numbers CID are used in describing instructions of the test scenario 52 illustrated in FIG. 8 to FIG. 10.

In the example of FIG. 5, when a timing at which a read packet is processed by the processing section STGA illustrated in FIG. 3 and a write packet is processed by the processing section STGA0 is generated (RDA2, WRA0), the decoding section CDEC sets the identification number CID to “1”. That is, if it is determined that a read packet was issued two cycles before a write packet, the decoding section CDEC sets the identification number CID to “1”.

Also, when a timing at which a write packet is processed by the processing section STGA0 and a response packet is processed in the processing section STGB1 is generated (WRA0, CPLB1), the decoding section CDEC sets the identification number CID to “2”. That is, if it is determined that a response packet of a packet issued a predetermined cycle before a write packet was issued, the decoding section CDEC sets the identification number CID to “2”.

Furthermore, when a timing at which a write packet is continuously processed by the processing sections STGA0, STGA1, and STGA2 is generated (WRA2, WRA1, and WRA0), the decoding section CDEC sets the identification number CID to “3”. That is, if it is determined that a write packet was issued continuously in three cycles, the decoding section CDEC sets the identification number CID to “3”.

As has been described above, the decoding section CDEC determines the order of at least two of the plurality of packets P11 and P21 received by the target device 10, based on the type information MT output from the target device 10. Then, the decoding section CDEC produces the identification number CID indicating the determined order (that is, a combination of the packets P11 and P21 that are processed by the target device 10). Note that a combination of a plurality of packets indicated by the identification number CID is not limited to the example of FIG. 5.

The decoding section CDEC is provided, so that the order of the packets P11 and P21 may be determined by taking out information indicating the packets P11 and P21 that are being processed from each of the processing sections STGA and STGB of the target device 10. Thus, the number of logics that are added to the target device 10 for a test may be reduced to a minimum, and thus, the logic of the target device 10 may be tested.

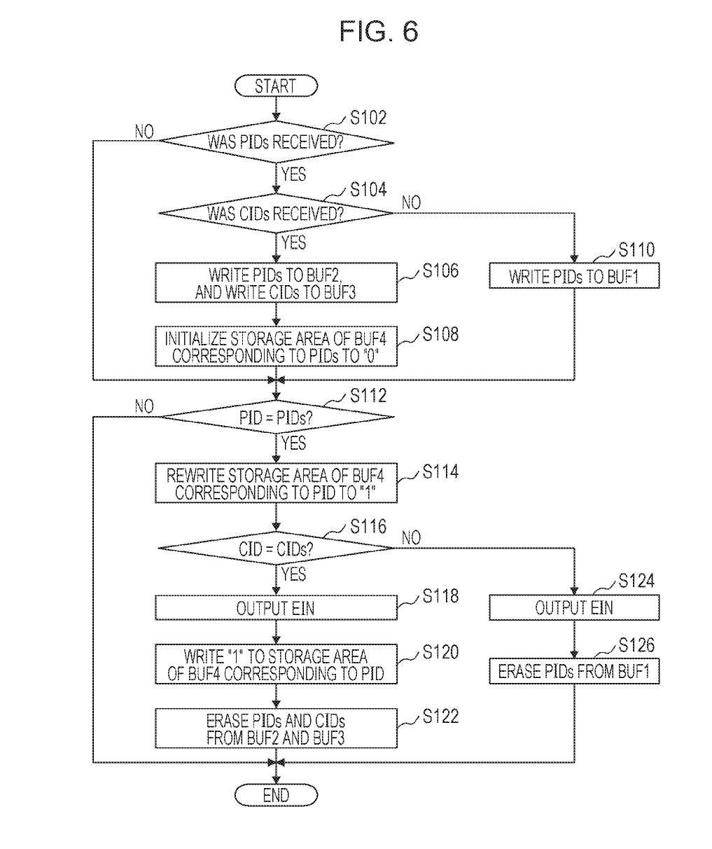

FIG. 6 illustrates an example of the operation of the error production section 40 illustrated in FIG. 4. The flow illustrated in FIG. 6 is repeatedly executed at predetermined intervals.

First, in Step S102, the error production section 40 determines whether or not the identification number PIDs indicating the packet P11 in which an error is to be embedded was received from the test scenario execution section 50. If the identification number PIDs was received, the process proceeds to Step S104, and, if the identification number PIDs was not received, the process proceeds to Step S112.

In Step S104, the error production section 40 determines whether or not the identification number CIDs indicating a condition for causing an error to be generated was received from the test scenario execution section 50. When the error production section 40 receives the identification number CIDs, the process proceeds to Step S106, and when the error production section 40 does not receive the identification number CIDs, the process proceeds to Step S110.

In Step S106, the error production section 40 writes the received identification number PIDs to the buffer BUF2 and the received identification number CIDs to the buffer BUF3. That is, if the condition indicated by the identification number CIDs is satisfied, the error production section 40 stores information used for causing an error to be in the packet P11 indicated by the identification number PIDs in the buffers BUF2 and BUF3.

Next, in Step S108, the error production section 40 initializes one of the storage areas of the buffer BUF4 which corresponds to the identification number PIDs received in Step S102 to “0”, which indicates that an error was not generated, and causes the process to proceed to Step S112.

In Step S110, the error production section 40 writes the received identification number PIDs to the buffer BUF1. That is, when the error production section 40 does not receive the identification number CIDs and receives the identification number PIDs, the error production section 40 stores information used for causing an error to be generated in the packet P11 indicated by the identification number PIDs without any condition in the buffer BUF1. Thereafter, the process is caused to proceed to Step S112.

In Step S112, the error production section 40 receives the identification number PID indicating the packet P11 received by the target device 10 from the target device 10. If the received identification number PID matches the identification number PIDs stored in one of the buffers BUF1 and BUF2, there is a probability that the error production section 40 causes an error to be generated in the packet P11, and therefore, the process is caused to proceed to Step S114. If the received identification number PID does not match any one of the identification numbers PIDs stored in the buffers BUF1 and BUF2, the error production section 40 does not embed an error in the packet P11, and therefore, the process is terminated. Determination in Step S112 is executed by the comparison sections CMP1 and CMP2 illustrated in FIG. 4.

In Step S114, one of the storage areas of the buffer BUF4, which corresponds to the received identification number PID, is rewritten to “1”. The error production section 40 receives the type information PTYP indicating the type of each of the plurality of packets P11 sequentially received by the target device 10 from the target device 10. The decoding section CDEC of the error production section 40 produces the identification number CID illustrating a combination of the plurality of packets P11 and P21 that are being processed by the target device 10, based on the received type information PTYP.

Next, in Step S116, the error production section 40 determines whether or not the produced identification number CID matches the identification number CIDs stored in one of the storage areas of the buffer BUF3, which corresponds to the identification number PID received from the target device 10. If the identification numbers CID and CIDs match each other, the process is caused to proceed to Step S118, and if the identification numbers CID and CIDs do not match each other, the process is caused to proceed to Step S124. Determination in Step S116 is executed by the determination sections JDG1 and JDG2 illustrated in FIG. 4.

In Step S118, the error production section 40 outputs the generation information EIN to the target device 10 in order to embed an error in the packet P11 indicated by the identification number PID. The target device 10 embeds an error in the packet P11 that is being processed in the processing section STGA0, based on the generation information EIN. Next, in Step S120, the error production section 40 writes “1” to one of the storage areas of the buffer BUF4, which corresponds to the identification number PID of the received packet P11. The buffer BUF4 outputs, as the error generation information EG, “1” stored in one of the storage areas, which corresponds to the identification number PID of the received packet P11, to the test scenario execution section 50 while the identification number PID is received.

Next, in Step S122, the error production section 40 erases the identification number PIDs which corresponds to the identification number PID of the packet P11 received by the target device 10 from the storage areas of the buffer BUF2. Also, the error production section 40 erases the identification number CIDs stored in one of the storage areas of the buffer BUF3, which corresponds to the identification number PID of the packet P11 received by the target device 10 (resets the identification number CIDs to “0”). Then, the error production section 40 terminates processing of causing, if a condition for a combination of a plurality of packets is satisfied, an error to be generated.

In Step S124, the error production section 40 outputs the generation information EIN to the target device 10 in order to embed an error in the packet P11 indicated by the identification number PID. The target device 10 embeds an error in the packet P11 that is being processed by the processing section STGA0, based on the generation information EIN. Next, in Step S126, the error production section 40 erases the identification number PIDs which corresponds to the identification number PID of the packet P11 received by the target device 10 from the storage areas of the buffer BUF1. Then, the error production section 40 terminates processing of embedding an error in the packet P11 designated by the identification number PIDs without designating a condition based on the identification number CIDs.

FIG. 7 illustrates an example of the operation of the response comparison section 54 of the test scenario execution section 50 illustrated in FIG. 2. The flow illustrated in FIG. 7 is repeatedly executed at predetermined intervals.

First, in Step S202, if the response comparison section 54 determines, based on the information CPL from the simulation device 20, that the simulation device 20 received the response packet P22, the response comparison section 54 causes the process to proceed to Step S204. If the response comparison section 54 determines, based on the information CPL from the simulation device 20, that the simulation device 20 did not receive the response packet P22, the response comparison section 54 terminates processing.

In Step S204, the response comparison section 54 determines whether or not the response packet P22 corresponds to a packet in which an error is to be generated, based on a packet combination condition (the identification number CIDs written to the buffer BUF3). That is, if an error is inserted in a write packet in which information that is to be read out by a read packet that is an original of the response packet P22 is written, based on the packet combination condition, the response comparison section 54 causes the process to proceed Step S206. On the other hand, if an error is not inserted in a write packet in which information that is to be read out by a read packet that is an original of the response packet P22 is written, based on the packet combination condition, the response comparison section 54 causes the process to proceed Step S214. That is, if an error is not inserted in the write packet or if an error is inserted in the write packet, based on the identification number PIDs, without designating the identification number CIDs, the response comparison section 54 causes the process to proceed to Step S214.

In Step S206, the response comparison section 54 reads out the value of the error generation information EG stored in one of the storage areas of the buffer BUF4, which corresponds to the identification number PID included in the response packet P22. Note that the identification number PID included in the response packet P22 has the same value as that of the identification number PID that identifies the read packet that is an original of the response packet P22.

Next, in Step S208, if the value of the error generation information EG is “1”, the response comparison section 54 determines that an error was inserted, based on that the packet combination condition based on the identification number CIDs is satisfied, and causes the process to proceed Step S210. On the other hand, if the value of the error generation information EG is “0”, the response comparison section 54 determines that the packet combination condition based on the identification number CIDs is not satisfied, and causes the process to proceed to Step S212.

In Step S210, the response comparison section 54 checks information included in the response packet P22 using an expectation value when an error is inserted, tests the logic of the target device 10, and terminates processing. If information (for example, read data) included in the response packet P22 matches the expectation value, the response comparison section 54 determines that the target device 10 correctly operated in accordance with the generated error. On the other hand, if the information included in the response packet P22 does not match the expectation value, the response comparison section 54 determines that the target device 10 malfunctioned in accordance with the generated error.

In Step S212, the response comparison section 54 checks information included in the response packet P22 using an expectation value when an error was not generated, tests the logic of the target device 10, and terminates processing. If the information included in the response packet P22 matches the expectation value, the response comparison section 54 determines that the target device 10 correctly operated, and if the information included in the response packet P22 does not match the expectation value, the response comparison section 54 determines that the target device 10 malfunctioned.

As has been described above, by changing the expectation value used for determination in accordance with the value of the error generation information EG, a test may be correctly executed each of a case where an error was embedded in the packet P11 and a case where an error was not embedded in the packet P11. Furthermore, two expectation values when an error was embedded in the packet P11 and when an error was not embedded in the packet P11 may be included in the test scenario 52, and the efficiency of a test may be increased, as compared to when a test is divided into multiple parts and thus is executed.

In Step S214, the response comparison section 54 checks information included in the response packet P22 using the expectation value, tests the logic of the target device 10, and terminates processing. If the information included in the response packet P22 matches the expectation value, the response comparison section 54 determines that the target device 10 correctly operated, and if the information included in the response packet P22 does not match the expectation value, the response comparison section 54 determines that the target device 10 malfunctioned. The processing in Step S214 includes checking when an error was embedded in a write packet, based on the identification number PIDs, without designating a condition based on the identification number CIDs, and checking when an error was not embedded in a write packet.

FIG. 8 illustrates an example of the test scenario 52 that is executed by the test scenario execution section 50 illustrated in FIG. 2. The test scenario execution section 50 outputs the test pattern TP to the simulation device 20 in accordance with the test scenario 52, causes the simulation device 20 to transmit the packet P11, and compares the information included in the response packet P22 received by the simulation device 20 with the expectation value. In FIG. 8, for convenience, on the left to the test scenario 52, line numbers for descriptions included in the test scenario 52 are illustrated.

In the test scenario 52, “//” indicates a comment line. “GenWtitePacket” indicates an instruction that causes the simulation device 20 to produce a write packet, and “GenReadPacket” indicates an instruction that causes the simulation device 20 to produce a read packet. “SetErrorPacketID” indicates an instruction to set a condition for causing an error to be generated in the error production section 40.

First, in a line 4, the test scenario execution section 50 causes the simulation device 20 to transmit a write packet (the identification number PID=ID1) that writes data DT1 in an area of the simulation device 30, which is indicated by an address AD1.

In a line 8, the test scenario execution section 50 causes the simulation device 20 to transmit a read packet (the identification number PID=ID1) that reads out data (the expectation value=DT1) from an area of the simulation device 30 which is indicated by the address AD1. Then, the response comparison section 54 of the test scenario execution section 50 compares the read data included in the response packet P22 (the identification number PID=ID1) from the simulation device 30, which responds to the read packet with the expectation value (DT1), and thereby, tests the logic of the target device 10.

Next, in a line 12, the test scenario execution section 50 sets the identification number PIDs (=ID2) indicating the write packet in which an error is to be embedded in the target device 10 and a condition CND1 in the error production section 40. As illustrated in FIG. 5, the condition CND1 is a condition where the target device 10 receives a read packet two cycles before receiving a write packet. That is, in the test scenario 52 illustrated in FIG. 8, an operation when an error was generated in the target device 10 that is currently processing packets in an order indicated in the condition CND1 is tested.

In a line 15, the test scenario execution section 50 causes the simulation device 20 to transmit a write packet (the identification number PID=ID2) that writes data DT2 in an area of the simulation device 30, which is indicated by an address AD2.

In a line 20, the test scenario execution section 50 causes the simulation device 20 to transmit a read packet (the identification number PID=ID2) that reads out data (the expectation value=DT2) from an area of the simulation device 30, which is indicated by the address AD2. An instruction described in a line 20 includes both of an expectation value DT2 when the condition CND1 is not satisfied and an error is not generated and an expectation value DT2′ when the condition CND1 is satisfied and an error is generated.

If the condition CND1 is not satisfied, the response comparison section 54 compares read data included in the response packet P22 from the simulation device 30, which responds to the read packet, with the expectation value DT2. On the other hand, if the condition CND1 is satisfied, the response comparison section 54 compares the read data included in the response packet P22 from the simulation device 30, which responds to the read packet, with the expectation value DT2′. Whether the condition CND1 is satisfied or is not satisfied is determined, based on the logic of the error generation information EG output from the buffer BUF4 illustrated in FIG. 4. Then, the test scenario execution section 50 tests the logic of the target device 10 by comparing the read data included in the response packet P22 with one of the expectation values DT2 and DT2′.

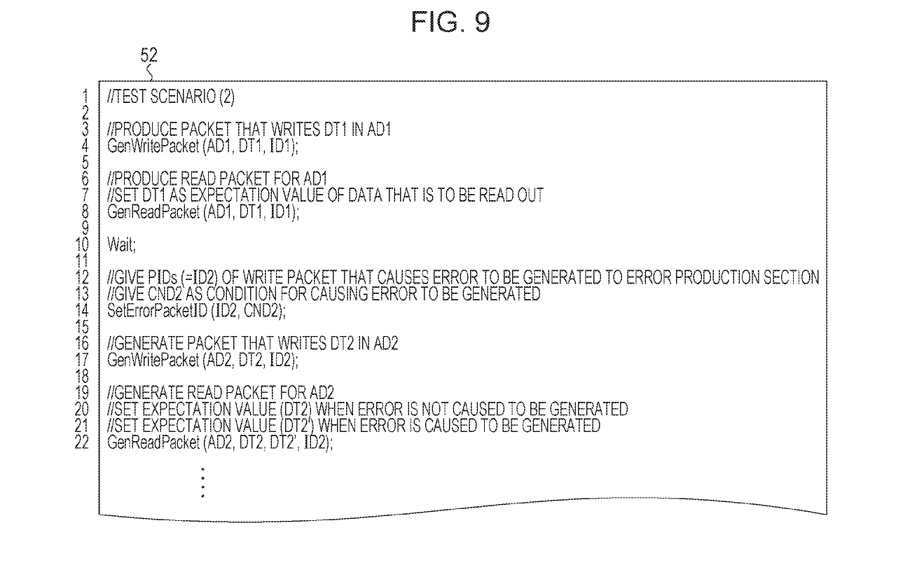

FIG. 9 illustrates another example of the test scenario 52 that is executed by the test scenario execution section 50 illustrated in FIG. 2. For each part that is the same as the corresponding part of FIG. 8, the detailed description thereof will be omitted. The descriptions of a line 4 and a line 8 are the same as those of a line 4 and a line 8 in FIG. 8, respectively. “Wait” described in a line 10 indicates an instruction to cause the simulation device 20 to wait, after transmitting a packet, for transmission of a next packet for a predetermined cycle. The descriptions of a line 17 and a line 22 are the same as those of a line 15 and a line 20 in FIG. 8, respectively.

In the line 10, the test scenario execution section 50 causes the simulation device 20 to wait, after transmitting a read packet described in the line 8, for transmission of a next write packet described in the line 17 for a predetermined cycle. Next, in a line 14, the test scenario execution section 50 sets the identification number PIDs (=ID2) indicating a write packet that causes an error to be generated in the target device 10 and a condition CND2 in the error production section 40. As illustrated in FIG. 5, the condition CND2 is a condition where, when the target device 10 receives a write packet, the response packet P22 is being processed by the processing section STGB1 illustrated in FIG. 3. That is, in the test scenario 52 illustrated in FIG. 9, an operation when an error was generated in the target device 10 that is currently processing packets in an order indicated in the condition CND2 is tested.

Then, after a predetermined cycle has passed, in the line 17, the test scenario execution section 50 causes the simulation device 20 to transmit a write packet (the identification number PID=ID2) that writes the data DT2 in an area of the simulation device 30, which is indicated by the address AD2.

In the line 22, similar to FIG. 8, the test scenario execution section 50 causes the simulation device 20 to transmit a read packet (the identification number PID=ID2) that reads out the data DT2 from an area of the simulation device 30, which is indicated by the address AD2. Then, if the condition CND2 is not satisfied, the response comparison section 54 compares read data included in the response packet P22 from the simulation device 30, which responds to the read packet with the expectation value DT2. On the other hand, if the condition CND2 is satisfied, the response comparison section 54 compares the read data included in the response packet P22 from the simulation device 30, which responds to the read packet, with the expectation value DT2′. Whether the condition CND2 is satisfied or is not satisfied is determined, based on the logic of the error generation information EG output from the buffer BUF4 illustrated in FIG. 4. Then, the test scenario execution section 50 tests the logic of the target device 10 by comparing the read data included in the response packet P22 with one of the expectation values DT2 and DT2′.

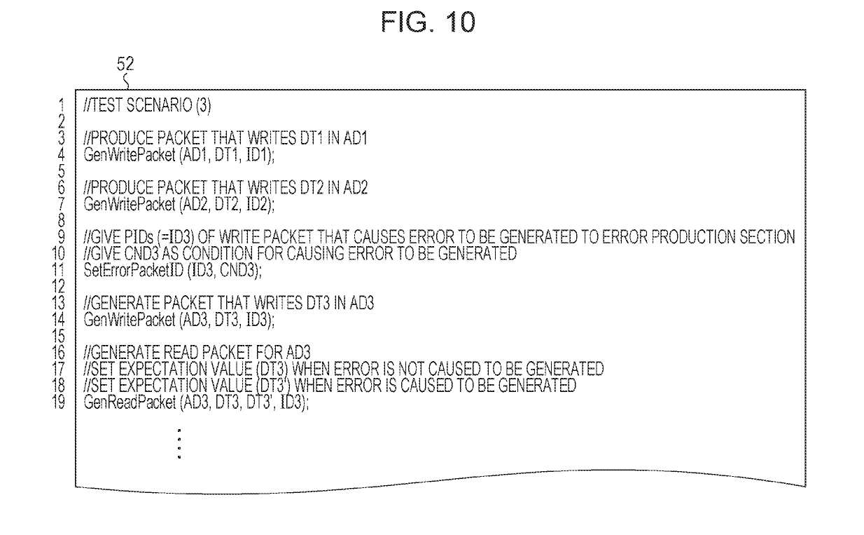

FIG. 10 illustrates another example of the test scenario 52 that is executed by the test scenario execution section 50 illustrated in FIG. 2. For each part that is the same as the corresponding part of FIG. 8, the detailed description thereof will be omitted. The descriptions of a line 4 and a line 7 are the same as those of the line 4 and the line 15 in FIG. 8, respectively.

In a line 11, the test scenario execution section 50 sets the identification number PIDs (=ID3) indicating a write packet that causes an error to be generated in the target device 10 and a condition CND3 in the error production section 40. As illustrated in FIG. 5, the condition CND3 is a condition where the target device 10 receives three consecutive write packets. That is, in the test scenario 52 illustrated in FIG. 10, an operation when an error was generated in the target device 10 that is currently processing the packets in an order indicated by the condition CND3.

Next, in the line 14, the test scenario execution section 50 causes the simulation device 20 to transmit a write packet (the identification number PID=ID3) that writes data DT3 in an area of the simulation device 30, which is indicated by an address AD3.

In a line 19, similar to FIG. 8, the test scenario execution section 50 causes the simulation device 20 to transmit a read packet (the identification number PID=ID3) that reads out the data DT3 from an area of the simulation device 30 which is indicated by the address AD3. Then, if the condition CND3 is not satisfied, the response comparison section 54 compares read data included in the response packet P22 from the simulation device 30, which responds to the read packet, with an expectation value DT3. On the other hand, if the condition CND3 is satisfied, the response comparison section 54 compares the read data included in the response packet P22 from the simulation device 30, which responds to the read packet, with an expectation value DT3′. Whether the condition CND3 is satisfied or is not satisfied is determined, based on the logic of the error generation information EG output from the buffer BUF4 illustrated in FIG. 4. Then, the test scenario execution section 50 tests the logic of the target device 10 by comparing the read data included in the response packet P22 with one of the expectation values DT3 and DT3′.

FIG. 11 illustrates an example of an information processing device that operates as a logic verification apparatus DT2 illustrated in FIG. 2.

An information processing device IPE illustrated in FIG. 11 includes a motherboard MB, an optical drive device ODD, a hard disk device HDD, an input device IND, an output device OUTD, and the like. A CPU, a main memory MM, an optical drive controller ODC, a hard disk controller HDC, an input interface INIF, an output interface OUTIF, a network interface NWIF, and the like are mounted on the motherboard MB. The CPU, the main memory MM, the optical drive controller ODC, the hard disk controller HDC, the input interface INIF, the output interface OUTIF, and the network interface NWIF are coupled to a system bus SBUS. The CPU, the main memory MM, the optical drive controller ODC, the hard disk controller HDC, the input interface INIF, the output interface OUTIF, and the network interface NWIF may be mounted on a common semiconductor chip.

An operating system that is executed by the CPU, a test program used for causing the information processing device IPE to function as the logic verification apparatus DT2, and the test scenario 52 are stored in the main memory MM. The information processing device IPE executes the test program, thereby realizing the target device 10, the simulation devices 20 and 30, the error production section 40, and the test scenario execution section 50, which are illustrated in FIG. 2. Then, the information processing device IPE operates as a simulator that tests the logic of the target device 10.

The optical drive controller ODC is coupled to the optical drive device ODD and may access a recording medium RM that is attached to the optical drive device ODD. The recording medium RM is a compact disc (CD) (registered Trademark), a digital versatile disc (DVD) (registered Trademark), or the like. The hard disk controller HDC is coupled to the hard disk drive HDD. The test program and the test scenario 52 are transferred to the main memory MM from the recording medium RM via the hard disk drive HDD. Note that the test program and the test scenario 52 may be transferred directly to the main memory MM from the recording medium RM.

The input interface INIF is coupled to the input device IND, such as a keyboard, a mouse, and the like. The output interface OUTIF is coupled to the output device OUTD, such as a display, a printer, and the like. The network interface NWIF is coupled to a network NW. The information processing device IPE may transfer the test program or the test scenario 52 stored in a device on the network NW to the hard disk drive HDD and the main memory MM via the network NW.

As has been described above, also in the embodiment illustrated in FIG. 2 to FIG. 11, similar to the embodiment illustrated in FIG. 1, a test of an operation of the target device 10 may be executed with a complex condition designated, as compared to a known technology, and a detailed test may be executed. Also, both of a test when an error was generated and a test when an error was not generated may be executed using one of two expectation values. As a result, the test pattern TP used for testing the logic of the target device 10 may be shortened, as compared to a known technology, a time which it takes to test the target device 10 may be reduced, as compared to a known technology, and the efficiency of a test may be increased.

Furthermore, in the embodiment illustrated in FIG. 2 to FIG. 11, the following advantages may be achieved. Both when a condition of the order in which the packet P11 is supplied to the target device 10 is included and when the condition is not included, an error may be embedded in the packet P11, and therefore, the logic of the target device 10 may be tested using various conditions.

Each of the buffers BUF1, BUF2, and BUF3 includes a plurality of storage areas, and therefore, a plurality of conditions for causing an error to be generated may be designated, so that the efficiency of a test may be further increased. Furthermore, the buffer BUF4 includes a plurality of storage areas, and therefore, a plurality of types of tests may be executed in accordance with a single test scenario 52, so that the efficiency of a test may be increased. Also, the buffer BUF4 is commonly used both when the order of the packet P11 is designated and when the order of the packet P11 is not designated, and thus, the scale of the logic verification apparatus DT2 is not increased.

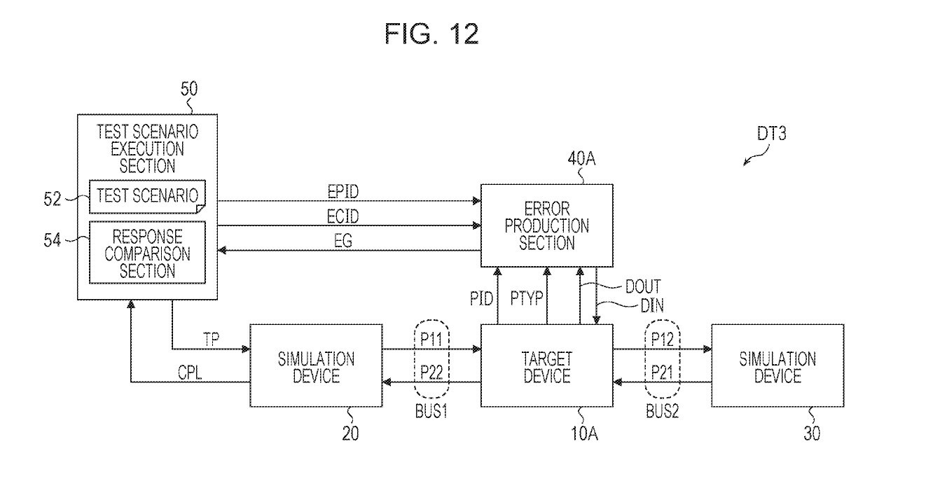

FIG. 12 illustrates another embodiment for a logic verification apparatus, a logic verification method, and a test program. Each component that is the same as or similar to the corresponding component of FIG. 2 is denoted by the same reference character as that of the corresponding component of FIG. 2, and the detailed description thereof will be omitted. A logic verification apparatus DT3 according to this embodiment includes a target device 10A, simulation devices 20 and 30, an error production section 40A, and a test scenario execution section 50. That is, the logic verification apparatus DT3 includes, instead of the target device 10 and the error production section 40 of the logic verification apparatus DT2 illustrated in FIG. 2, the target device 10A and the error production section 40A.

The error production section 40A has a function of inserting an error in data that is transmitted to a data output line DOUT extended from the target device 10A and returning the data in which the error was inserted back to the target device 10A via a data input line DIN. The error production section 40A has a similar function to that of the error production section 40 illustrated in FIG. 2, except that the error production section 40A has a function of inserting an error in the target device 10A, instead of outputting the generation information EIN. Note that the target device 10A has a configuration obtained by removing, from the target device 10 illustrated in FIG. 2, the function of causing an error to be generated.

Similar to the logic verification apparatus DT1 illustrated in FIG. 2, the logic verification apparatus DT3 illustrated in FIG. 12 is realized by the information processing device IPE (FIG. 11) that executes a test program used for testing the logic of the target device 10A. An information processing device that executes a test program functions as a simulator, and executes an operation based on a logic verification method for testing the logic of the target device 10A.

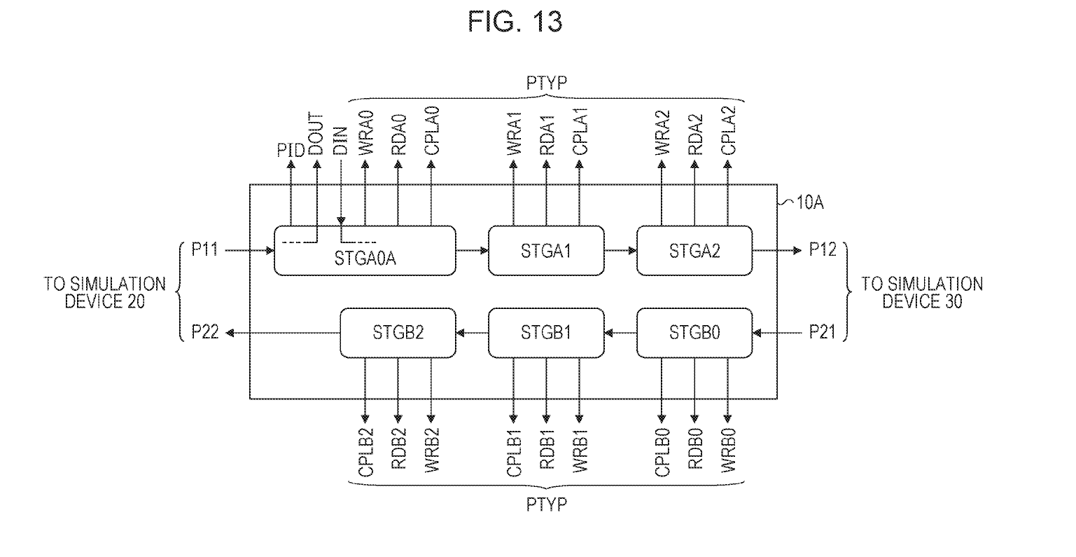

FIG. 13 illustrates an example of the target device 10A illustrated in FIG. 12. Each component that is the same as or similar to the corresponding component of the target device 10 illustrated in FIG. 3 is denoted by the same reference character as that of the corresponding component of the target device 10, and the detailed description thereof will be omitted. The target device 10A is similar to the target device 10 illustrated in FIG. 3, except that the target device 10A includes, instead of the processing section STGA0 illustrated in FIG. 3, a processing section STGA0A.

Similar to the processing section STGA0 illustrated in FIG. 3, the processing section STGA0A has a function of extracting an identification number PID included in a packet P11 received from the simulation device 20 and outputting the extracted identification number PID to the error production section 40A. Furthermore, the processing section STGA0A has a function of outputting at least a part of information included in the packet P11 to the error production section 40A via the data output line DOUT and rewriting the packet P11 using information that is received from the error production section 40A via the data input line DIN.

If the error production section 40A inserts an error in the information received via the data output line DOUT and outputs the information to the data input line DIN, the processing section STGA0A processes the packet P11 in which an error is inserted. On the other hand, if the error production section 40A does not change the information received via the data output line DOUT and outputs the information to the data input line DIN, the processing section STGA0A processes the original packet P11 in which an error is not inserted.

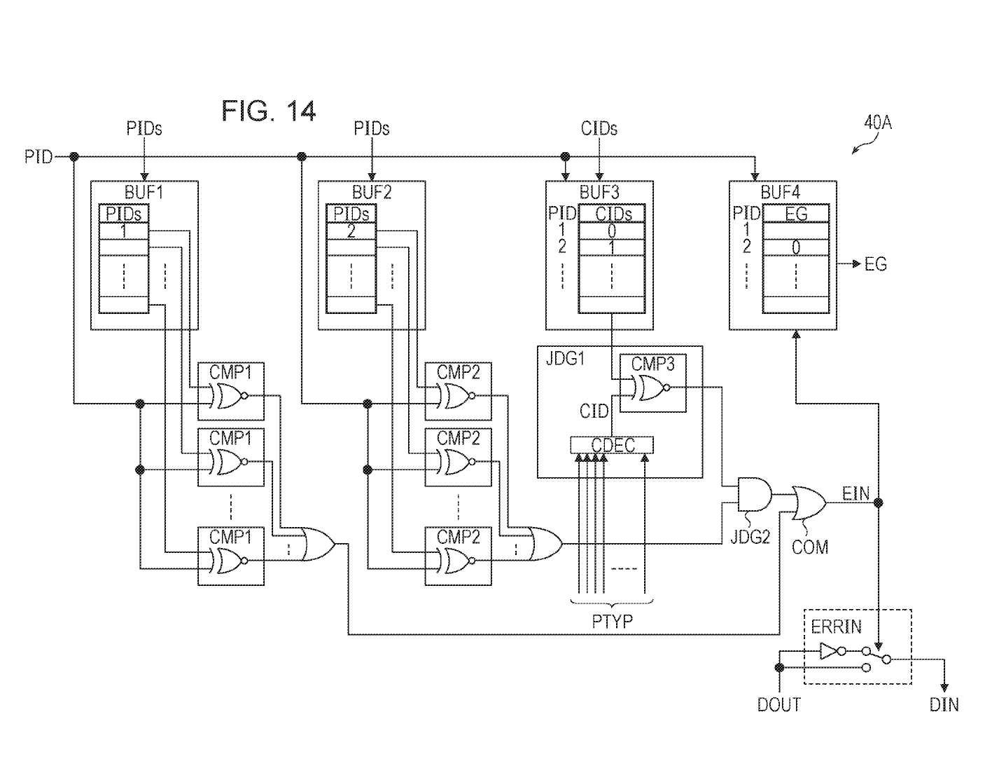

FIG. 14 illustrates an example of the error production section 40A illustrated in FIG. 12. The error production section 40A has a similar function to that of the error production section 40 illustrated in FIG. 2, except that the error production section 40A has a configuration obtained by adding an error insertion section ERRIN to the error production section 40 illustrated in FIG. 2. If the generation information EIN indicates that an error was generated, the error insertion section ERRIN inverts the logic of data transmitted to the data output line DOUT and outputs the inverted data to the data input line DIN, thereby causing an error to be generated in the target device 10A. If the generation information EIN does not indicate that an error was generated, the error insertion section ERRIN does not change data transmitted to the data output line DOUT and outputs the data to the data input line DIN. In this case, an error is not caused to be generated in the target device 10A.

The error insertion section ERRIN is provided in the error production section 40A, and thus, an error may be embedded in the packet P11 that is processed by the target device 10A without adding a logic for generating an error to the target device 10A. Thus, the logic of the target device 10A may be tested using design data, such as a circuit description of an actual device and the like. Note that the error insertion section ERRIN may fix the logic of data transmitted to the data output line DOUT to a predetermined logic (a logic 0 or a logic 1), and output the data the logic of which is fixed to the data input line DIN, thereby causing an error to be generated in the target device 10A.

As has been described above, also in the embodiment illustrated in FIG. 12 to FIG. 14, similar to the embodiments illustrated in FIG. 1 to FIG. 11, a test of an operation of the target device 10A may be executed with a complex condition designated, as compared to a known technology, and a detailed test may be executed. Also, a test is executed using two expectation values, and thus, a time which it takes to test the target device 10A may be reduced, as compared to a known technology. A plurality of storage areas is provided in each of the buffers BUF1, BUF2, BUF3, and BUF4, and thus, a test may be executed in accordance with a plurality of conditions for causing an error to be generated. Based on the foregoing, the efficiency of a test may be increased.

Furthermore, in the embodiment illustrated in FIG. 12 to FIG. 14, an error is embedded in the packet P11 that is processed by the target device 10A by the error insertion section ERRIN, and thereby, the logic of the target device 10A may be tested using design data, such as a circuit description of an actual device and the like. Thus, the efficiency of a test may be further increased.

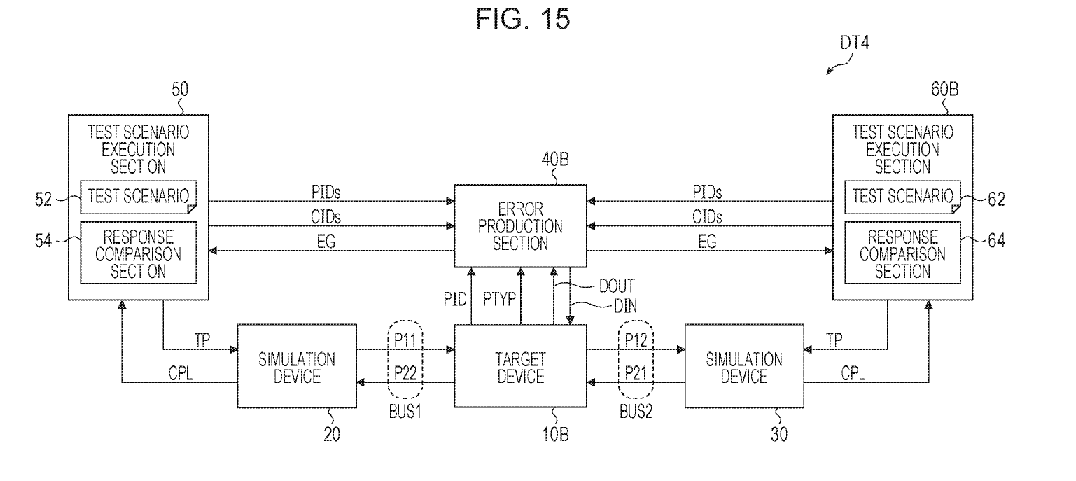

FIG. 15 illustrates another embodiment for a logic verification apparatus, a logic verification method, and a test program. Each component that is the same as or similar to the corresponding component of FIG. 2 is denoted by the same reference character as that of the corresponding component of FIG. 2, and the detailed description thereof will be omitted. A logic verification apparatus DT4 according to this embodiment includes a target device 10B, simulation devices 20 and 30, an error production section 40B, and test scenario execution sections 50 and 60B. That is, the logic verification apparatus DT4 includes, instead of the error production section 40 of the logic verification apparatus DT2 illustrated in FIG. 2, the error production section 40B, and further includes the test scenario execution section 60B coupled to the error production section 40B and the simulation device 30. Also, the logic verification apparatus DT4 includes, instead of the target device 10 illustrated in FIG. 2, the target device 10B.

Similar to the test scenario execution section 50, the test scenario execution section 60B includes a test scenario 62 and a response comparison section 64. In accordance with the test scenario 62, the test scenario execution section 60B outputs a test pattern TP that causes the simulation device 30 to operate to the simulation device 30, and also outputs identification numbers PIDs and CIDs to the error production section 40B. When the identification number CIDs is not designated, the identification number PIDs is designated, and an error is embedded in a packet P21, the test scenario execution section 60B causes the response comparison section 64 to compare information CPL included in a response packet P12 with an expectation value, regardless of error generation information EG. On the other hand, when the identification number PIDs is designated as well as the identification number CIDs (an error generation condition) and an error is embedded in the packet P21, the test scenario execution section 60B causes the response comparison section 64 to execute comparison based on the error generation information EG. That is, similar to the response comparison section 54 illustrated in FIG. 2, the response comparison section 64 compares the information CPL included in the response packet P12 with one of two expectation values. An example of the operation of the response comparison section 64 is similar to the example of the operation of the response comparison section 54 illustrated in FIG. 7.

The test scenario 62 that is executed by the test scenario execution section 60B is similar to the test scenario 52 illustrated in FIG. 8 to FIG. 10, except that the simulation device 30 transmits the packet P21 and the simulation device 20 transmits the packet P11.

Similar to the target device 10A illustrated in FIG. 13, the target device 10B includes a plurality of processing sections STGA that sequentially process the packet P11 and a plurality of processing sections STGB that sequentially process the packet P21. In this regard, similar to the processing section STGA0A, a processing section STGB0 has a function of outputting the identification number PID to the error production section 40B. Also, similar to the processing sections STGA0A, the processing section STGB0 has a function of outputting at least a part of the information included in the packet P21 to a data output line DOUT and a function of rewriting the packet P11 using information that is received via a data input line DIN. That is, a signal line through which the identification number PID is transmitted, the data output line DOUT, and the data input line DIN are provided so as to correspond to each of the packet P11 and the packet P21.

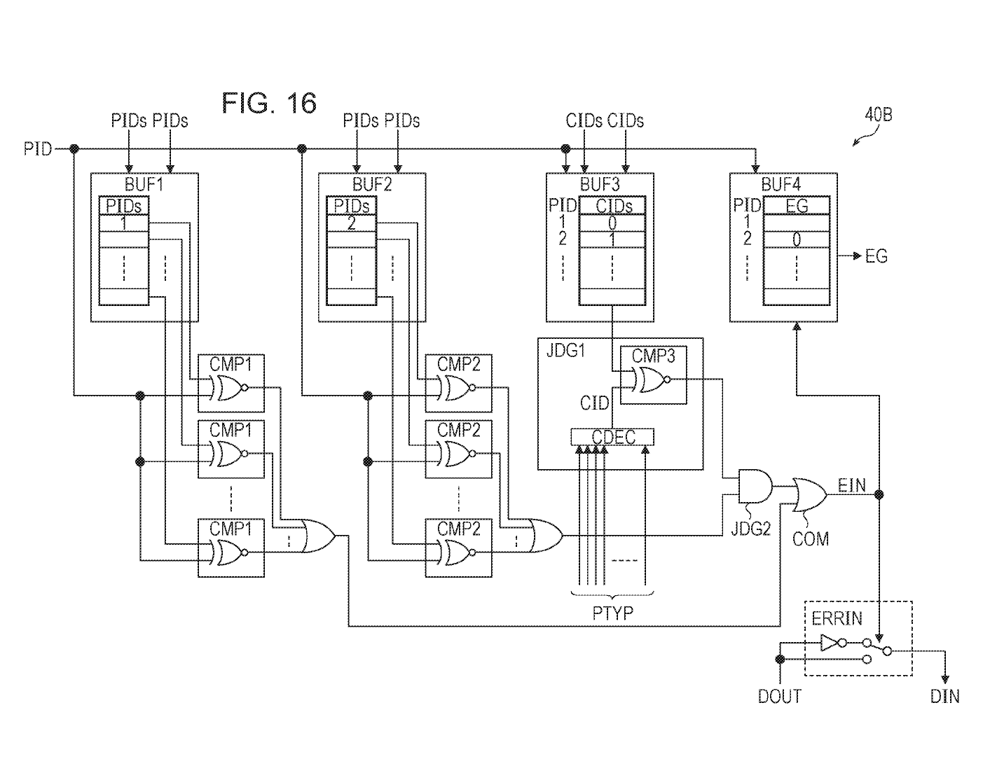

FIG. 16 illustrates an example of the error production section 40B illustrated in FIG. 15. The error production section 40B has a similar function to that of the error production section 40A illustrated in FIG. 14. In this regard, buffers BUF1 and BUF2 of the error production section 40B hold not only the identification number PIDs from the test scenario execution section 50 but also the identification number PIDs from the test scenario execution section 60B. Also, a buffer BUF3 of the error production section 40B holds not only the identification number CIDs from the test scenario execution section 50 but also the identification number CIDs from the test scenario execution section 60B.

Then, the error production section 40B inserts an error in data that is received via the data output line DOUT, based on the identification numbers PIDs and CIDs held in the buffers BUF1 to BUF3. An example of the operation of the error production section 40B is similar to that of FIG. 6. Note that the error insertion section ERRIN embeds an error in information included in the packet P11 or information of the packet P21 indicated by the identification number PIDs. Thus, the logic verification apparatus DT4 may include the error production section 40B for the packet P11 and the error production section 40B for the packet P21.

Similar to the logic verification apparatus DT1 illustrated in FIG. 2, the logic verification apparatus DT4 illustrated in FIG. 15 is realized by the information processing device IPE (FIG. 11) that executes a test program used for testing the logic of the target device 10B. The information processing device that executes the test program functions as a simulator, and executes an operation based on a logic verification method for testing the logic of the target device 10B.

As has been described above, also in the embodiment illustrated in FIG. 15 and FIG. 16, similar to the embodiments illustrated in FIG. 1 to FIG. 14, a test of an operation of the target device 10B may be executed with a complex condition designated, as compared to a known technology, and a detailed test may be executed. Also, both of a test when an error was generated and a test when an error was not generated may be executed using one of two expectation values, and thus, a time which it takes to test the target device 10B may be reduced, as compared to a known technology.

Furthermore, in the embodiment illustrated in FIG. 15 and FIG. 16, the logic of the target device 10B in which an error is embedded in each of the packet P11 that is transmitted from the simulation device 20 and the packet P21 that is transmitted from the simulation device 30 may be tested. As a result, the efficiency of a test may be further increased.

Note that the test scenario execution section 60B illustrated in FIG. 15 may be added to the logic verification apparatus DT2 illustrated in FIG. 2. In this case, the buffers BUF1 and BUF2 of the error production section 40 illustrated in FIG. 4 hold not only the identification number PIDs from the test scenario execution section 50 but also the identification number PIDs from the test scenario execution section 60B. Also, the buffer BUF3 of the error production section 40 illustrated in FIG. 4 holds not only the identification number CIDs from the test scenario execution section 50 but also the identification number CIDs from the test scenario execution section 60B.

Features and advantages of embodiments will become apparent from the detailed description above. It is intended that the scope of the appended claims includes the features and advantages of the embodiments as described above without departing from the spirit and scope of the present disclosure. In addition, a person ordinarily skilled in the art of the present disclosure would easily arrive at all modifications and variations. Therefore, it is not intended to limit the range of inventive embodiments to the above-described embodiments, and it is also possible to make suitable modifications and equivalents within the disclosed scope herein.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A logic verification apparatus configured to sequentially transfer a plurality of instructions that are sequentially received from a simulation arithmetic processing device that simulates an operation of an arithmetic processing device to a simulation I/O device that simulates an operation of an I/O device and to test an operation of a simulation device under test that processes a plurality of responses that are sequentially received from the simulation I/O device in accordance with the plurality of instructions transferred to the simulation I/O device, the logic verification apparatus comprising:
an error generation section configured to cause, when the simulation device receives at least one of the plurality of instructions and the plurality of responses and a target instruction from the simulation arithmetic processing device in a predetermined order, an error to be generated in a result of processing of the target instruction performed by the simulation device;
an error holding section configured to hold error generation information indicating that the error was generated in a result of processing of the target instruction; and
a response comparison section configured to compare a target response, among the plurality of responses received by the simulation device, which corresponds to the target instruction, with one of a plurality of expectation values, based on the error generation information held in the error holding section.

2. The logic verification apparatus according to claim 1, wherein
the error generation section includes
a first holding section configured to hold target instruction information indicating the target instruction,
a first detection section configured to detect that one of the plurality of instructions received by the simulation device is the target instruction that corresponds to the target instruction information held by the first holding section,
a second holding section configured to hold order information indicating a predetermined order,
a second detection section configured to detect that an order of at least two of the plurality of instructions and the plurality of responses received by the simulation device is an order that corresponds to the order information held by the second holding section, and
a determination section configured to cause the error to be generated, based on detection performed by the first detection section and detection performed by the second detection section.

3. The logic verification apparatus according to claim 2, wherein
the first holding section includes a plurality of first storage areas each of which holds the corresponding one of the plurality of pieces of target instruction information each of which indicates the corresponding one of the plurality of target instructions,
the first detection section detects that an instruction received by the simulation device is one of the target instructions that correspond to the plurality of pieces of target instruction information held by the plurality of the first storage areas,
the second holding section includes a plurality of second storage areas each of which holds the corresponding one of the plurality of pieces of order information in accordance with the plurality of pieces of the target instruction information held in the first holding section, and
the second detection section detects that the order of at least two of the plurality of instructions and the plurality of responses received by the simulation device is an order that corresponds to one of the plurality of pieces of order information held in the second storage areas which corresponds to the target instruction received by the simulation device.

4. The logic verification apparatus according to claim 3, wherein
the error holding section includes a plurality of third storage areas each of which holds the corresponding one of the plurality of pieces of error generation information in accordance with the plurality of pieces of target instruction information held in the first holding section.

5. The logic verification apparatus according to claim 2, wherein
the second detection section includes
a decoding section configured to determine the order of at least two of the plurality of instructions and the plurality of responses received by the simulation device, based on instruction information indicating the plurality of instructions and the plurality of responses sequentially received by the simulation device, and
an order comparison section configured to compare the order determined by the decoding section with an order corresponding to the order information held in the second storage area.

6. The logic verification apparatus according to claim 2, wherein
the error generation section includes
a third holding section configured to hold target instruction information that is different from the target instruction information held by the first holding section, and
a third detection section configured to detect that one of the plurality of instructions received by the simulation device is the target instruction indicated by the target instruction information held by the third holding section, and
the determination section includes
a combining section configured to cause the error to be generated,
based on one of detection performed by the first detection section and the second detection section and detection performed by the third detection section.

7. The logic verification apparatus according to claim 2, further comprising:
a test scenario execution section configured to cause the simulation arithmetic processing device to transmit an instruction and output the target instruction information and the order information to the error generation section in accordance with a test scenario, and refer to a response received by the simulation device from the simulation I/O device,
wherein
the response comparison section is included in the test scenario execution section.

8. The logic verification apparatus according to claim 7, wherein
the plurality of instructions includes a write packet that writes data in the simulation I/O device and a read packet that reads data from the simulation I/O device,
the plurality of responses includes a write response packet that is transmitted from the simulation I/O device, based on the write packet, and a read response packet including data that is transmitted from the simulation I/O device, based on the read packet, and is read out from the simulation I/O device,
the error generation section causes an error to be generated in data included in the write packet, and
the response comparison section compares data included in the read response packet with one of the plurality of expectation values.

9. A logic verification method for causing an information processing device to execute a process, the logic verification method being configured to sequentially transfer a plurality of instructions that are sequentially received from a simulation arithmetic processing device that simulates an operation of an arithmetic processing device to a simulation I/O device that simulates an operation of an I/O device and to test an operation of a simulation device under test that processes a plurality of responses that are sequentially received from the simulation I/O device in accordance with the plurality of instructions transferred to the simulation I/O device, the process comprising:
generating, when the simulation device receives at least one of the plurality of instructions and the plurality of responses and a target instruction from the simulation arithmetic processing device in a predetermined order, an error in a result of processing of the target instruction performed by the simulation device;
holding, in an error holding section, error generation information indicating that an error was generated in a result of processing of the target instruction; and
comparing a target response, among the plurality of responses received by the simulation device, which corresponds to the target instruction, with one of a plurality of expectation values, based on the error generation information held in the error holding section.

10. A non-transitory and computer-readable storage medium storing a test program configured to sequentially transfer a plurality of instructions that are sequentially received from a simulation arithmetic processing device that simulates an operation of an arithmetic processing device to a simulation I/O device that simulates an operation of an I/O device and to test an operation of a simulation device under test that processes a plurality of responses that are sequentially received from the simulation I/O device in accordance with the plurality of instructions transferred to the simulation I/O device, the test program for causing an information processing device to execute a process, the process comprising:
generating, when the simulation device receives at least one of the plurality of instructions and the plurality of responses and a target instruction from the simulation arithmetic processing device in a predetermined order, an error in a result of processing of the target instruction performed by the simulation device;
holding, in an error holding section, error generation information indicating that an error was generated in a result of processing of the target instruction; and
comparing a target response, among the plurality of responses received by the simulation device, which corresponds to the target instruction, with one of a plurality of expectation values, based on the error generation information held in the error holding section.
